(19) United States
(12) Patent Application Publication
(10) Pub. No.: US 2017/0194928 A1
(43) Pub. Date: Jul. 6, 2017

(54) COUPLING CIRCUITS FOR USE WITH UNIVERSAL POWER OVER ETHERNET

(71) Applicant: FOXCONN INTERCONNECT TECHNOLOGY LIMITED, Grand Cayman (KY)

(72) Inventors: YONG-CHUN XU, Kunshan (CN); PING-CHANG TU, New Taipei (TW)

(21) Appl. No.: 15/394,837

(22) Filed: Dec. 30, 2016

(30) Foreign Application Priority Data
Dec. 31, 2015 (CN) 201511013369.7

(51) Int. Cl. H03H 7/06; H04B 3/54; H01F 27/29

(52) U.S. Cl. CPC H03H 7/06; H01F 27/29; H04B 3/54

(57) ABSTRACT

The network filtering circuit includes a cable side for connection with a network cable, a physical side for connection with a mother board, and a plurality of transmission channels connected between the cable side and the physical side. Each of the transmission channels includes an autotransformer with a center tap sequentially connected by a capacitor and a resistor in series connection wherein a power supply is connected to a position of a circuit between the capacitor and the center tap, and another capacitor having a higher capacitance is linked to the resistor opposite to the capacitor. All transmission channels share the same capacitor having the higher capacitance to a same ground node.

### BACKGROUND OF THE INVENTION

1. Field of the Invention

The present invention relates to a network filtering circuit, and more particularly to a network filtering circuit for use with the so-called UPOE (Universal Power Over Ethernet) circuit network.

2. Description of Related Arts

Chinese Patent No. CN204733134U issued on Oct. 28, 2015, discloses a network filtering circuit including a cable side, a physical side, and a plurality of differential pair transmission channels connected therebetween. Each of the transmission channels includes an autotransformer, two first capacitors, and a CMC (Common Mode Choke). Each differential pair transmission channel includes a first transmission line and a second transmission line with the autotransformer connected between the first transmission line and the second transmission line. The two first capacitors is respectively linked with the corresponding first transmission line and second transmission line in series connection. The CMC includes a first coil connected with the first transmission line, and a second coil connected with the second transmission line, wherein the center taps of the first, second and third transmission channels are initially linked together in parallel connection and successively linked with the resistor and the capacitor to reach the grounding node while the autotransformer of the fourth channel is connected to another ground node through another capacitor. With such an arrangement, it is asserted that such a filtering circuit may be used in the printed circuit board complying with POE standard.

Anyhow, in such an arrangement only three transmission channels are equipped with the corresponding resistors and capacitors, and the remaining transmission channel only has the capacitor, thus failing to efficiently implement the current POE circuit, needless to say using in the UPOE circuits

### SUMMARY OF THE INVENTION

Accordingly, an object of the present invention is to provide network filtering circuit for use with the UPOE standard. The invention includes a cable side for connection with a network cable, a physical side for connection with a mother board, and a plurality of differential pair transmission channels connected between the cable side and the physical side. Each of the transmission channels includes an autotransformer, two first capacitors, and a CMC. Each of the transmission channels includes a first transmission line, a second transmission line with the autotransformer connected therebetween. The two first capacitors are linked with the corresponding first transmission line and second transmission line, respectively. The CMC includes a first coil and a second coil coupled with each other and respectively connected to the corresponding first transmission line and second transmission line in series connection. The autotransformer is equipped with center taps. The filtering circuit further includes a second capacitor, the resistor, the third capacitor wherein the second capacitor is connected with the center taps, the third capacitor is connected to the ground node, the second capacitor and the corresponding center tap are equipped with an external power line therebetween so as to provide at least 60 Watts for those four transmission channels.

Compared with the prior arts, the network filtering circuit has the features including provision of the second capacitors connected to the center taps, the resistors connected with the second capacitors, the third capacitors linked between the resistors and the ground node. The second capacitor and the corresponding center tap are equipped with an external power line so as to have all four transmission channels provided with power, thus meeting the requirement of power provision in the UPOE circuit under a low cost. Notably, combining the autotransformer with the UPOE circuit may achieved the desired return loss and the lower cost.

Other objects, advantages and novel features of the invention will become more apparent from the following detailed description when taken in conjunction with the accompanying drawings.

### BRIEF DESCRIPTION OF THE DRAWING

FIG. 1 is a network filtering circuit according to the invention.

### DETAILED DESCRIPTION OF THE PREFERRED EMBODIMENT

Reference will now be made in detail to some preferred embodiments of the present invention.

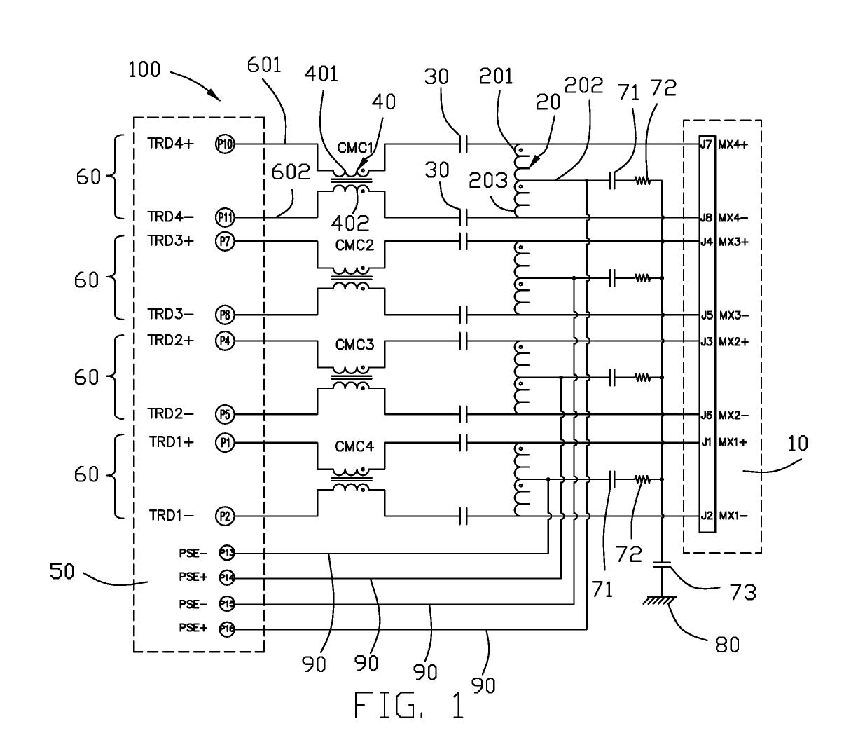

Referring to FIG. 1, a network filtering circuit 100 according to the invention. The network filtering circuit 100 includes a cable side 10 for connection with a network cable, a physical side 50 for connection with a mother board, and a plurality of transmission channels 60 connected between the cable side 10 and the physical side 11.

Each of the transmission channels 60 includes an autotransformer 20, two first capacitors 30 and a CMC 40. Each transmission channel 60 includes a first transmission wire/line 601 and a second transmission wire/line 602 for transmitting a pair of different signals, and the corresponding autotransformer 20 linked between the first transmission line 601 and the second transmission line 602. The CMC 40 includes a first coil 401 and a second coil 402 coupled with each other wherein the first coil 401 is linked to the first transmission line 601 and the second coil 402 is linked to the second transmission line 602 in series connection.

The autotransformer 20 includes a center tap 202 located between and respectively connected to the first connection end 201 of the first transmission line 601 and the second connection end 203 of the second transmission line 602. A second capacitor 71 and the resistor 72 are linked to the corresponding center tap 202 in series connection wherein the second capacitor 71 is directly connected to the center tap 202. All four resistors 72 are connected together in parallel connection and commonly linked to a same third capacitor 73 which is directly connected to a ground node 80. A power supply line 90 is provided between the center tap 202 and the corresponding second capacitor 71 so as to provide at least 60 Watts loading, thus meeting the UPEO criteria.

The autotransformer 20 is located closer to the cable side 10 while the CMC 40 is closer to the physics side 50. The two first capacitors 30 are located between the CMC 40 and the autotransformer 20.

The value of the resistor 72 is 75 Ω. The value of the second capacitor 71 is 0.022 uF. The value of the third capacitor 73 is 1000 pF. The value of the first capacitor 30 is 0.1 uF.

In brief, the second capacitor 71, the resistor 72 and the third capacitor 73 are linked with one another in series connection wherein the second capacitor 72 is directly connected to the center tap 202, the third capacitor 73 shared by four transmission channels 60 is directly connected to the ground node 80, and the power supply lines 90 respectively connect to the corresponding transmission channels 60 at a position between the corresponding autotransformer 20 and the corresponding second capacitor 71. Each of all four transmission channels 60 has its own second capacitor 71, the resistor 72 and the power supply line 90 while sharing the same third capacitor 73 before reaching the ground node 90. This arrangement allows the UPOE circuit and the autotransformer circuit to be combined together for achieving the desired return loss and the low cost.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A network filtering circuit comprising:
a cable side for connection to a network cable;
a physical side for connection to a mother board; and
a plurality of transmission channels connected between the cable side and the physical side, each transmission channel comprising:
a first transmission line and a second transmission line, a common mode choke having a first coil and a second coil respectively connected to the corresponding first transmission line and second transmission line, respectively;
two first capacitors respectively connected to the corresponding first transmission line second transmission line;
an autotransformer connected between the first transmission line and the second transmission line and opposite to the corresponding common mode choke with the first capacitors therebetween;
a center tap extending from the autotransformer;
a second capacitor and a resistor sequentially linked to the center tap in series connection; and
a power supply independently connected to a position of a circuit linked between the center tap and the second capacitor.

2. The network filtering circuit as claimed in claim 1, wherein each of said transmission channel further includes a third capacitor connected between the resistor and a ground node in series connection.

3. The network filtering circuit as claimed in claim 2, wherein all said transmission channels share the same third capacitor and ground node.

4. The network filtering circuit as claimed in claim 1, wherein there are four transmission channels with at least 60 Watts power supply.

5. The network filtering circuit as claimed in claim 1, wherein the autotransformer is closer to the cable side while the common mode choke is closer to said physical side.

6. The network filtering circuit as claimed in claim 1, wherein a value of the resistor is 75 Ω.

7. The network filtering circuit as claimed in claim 1, wherein a value of the second capacitor is 0.022 uF while that of the third capacitor is 1000 pF.

8. A network filtering circuit comprising:
a cable side for connection to a network cable;
a physical side for connection to a mother board; and
a plurality of transmission channels connected between the cable side and the physical side, each transmission channel comprising:
a first transmission line and a second transmission line, a common mode choke having a first coil and a second coil respectively connected to the corresponding first transmission line and second transmission line, respectively;
two first capacitors respectively connected to the corresponding first transmission line second transmission line;
an autotransformer connected between the first transmission line and the second transmission line;
a center tap extending from the autotransformer;
a second capacitor and a resistor sequentially linked to the center tap in series connection;
a third capacitor linked behind the resistor and connected to a ground node in series connection; and
a power supply independently connected to a position of a circuit linked between the center tap and the second capacitor.

9. The filtering network as claimed in claim 8, wherein all said transmission channels share the same third capacitor and ground node.

10. The network filtering circuit as claimed in claim 8, wherein there are four transmission channels with at least 60 Watts power supply.

11. The network filtering circuit as claimed in claim 8, wherein the autotransformer is closer to the cable side while the common mode choke is closer to said physical side.

12. The network filtering circuit as claimed in claim 8, wherein a value of the resistor is 75 Ω.

13. The network filtering circuit as claimed in claim 8, wherein a value of the second capacitor is 0.022 uF while that of the third capacitor is 1000 pF.

14. A network filtering circuit comprising:
a cable side for connection to a network cable;
a physical side for connection to a mother board; and
a plurality of transmission channels connected between the cable side and the physical side, each transmission channel comprising:
a first transmission line and a second transmission line, a common mode choke having a first coil and a second coil respectively connected to the corresponding first transmission line and second transmission line, respectively;
two first capacitors respectively connected to the corresponding first transmission line second transmission line;
an autotransformer connected between the first transmission line and the second transmission line and opposite to the corresponding common mode choke with the first capacitors therebetween;
a center tap extending from the autotransformer;
a second capacitor and a resistor sequentially linked to the center tap in series connection;
a third capacitor linked behind the resistor and connected to a ground node in series connection; and
a power supply connected to a position of a circuit linked between the center tap and the second capacitor.

15. The filtering network as claimed in claim 14, wherein all said transmission channels share the same third capacitor and ground node.

16. The network filtering circuit as claimed in claim 14, wherein there are four transmission channels with at least 60 Watts power supply.

17. The network filtering circuit as claimed in claim 14, wherein the autotransformer is closer to the cable side while the common mode choke is closer to said physical side.

18. The network filtering circuit as claimed in claim 14, wherein a value of the resistor is 75 Ω.

19. The network filtering circuit as claimed in claim 14, wherein a value of the second capacitor is 0.022 uF while that of the third capacitor is 100 0 pF.
